(19) United States
(12) Patent Application Publication
(10) Pub. No.: US 2007/0077772 A1
(43) Pub. Date: Apr. 5, 2007

(54) Apparatus and method for manufacturing semiconductor device using plasma

(76) Inventor: Jun-Seuck Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/397,673

(22) Filed: Apr. 5, 2006

(30) Foreign Application Priority Data
Oct. 4, 2005 (KR) 2005-0092964

(51) Int. Cl. H01L 21/31; H01L 21/469

(52) U.S. Cl. 438/758; 438/780

(57) ABSTRACT

An apparatus and related manufacturing method for semiconductor devices are disclosed. A plasma generator is used to convert a plasma source into plasma. Plasma particles are then captured in plasma capsules formed from a protective layer, and introduced into a process chamber adapted to form a material layer on a semiconductor substrate using the plasma particles once they are liberated from the plasma capsules.

### BACKGROUND OF THE INVENTION

1. Technical Field

Embodiments of the invention relate to an apparatus and a method for manufacturing semiconductor devices. More particularly, embodiments of the invention relate to an apparatus and a method for manufacturing semiconductor devices using plasma.

This application claims the benefit of Korean Patent Application No. 2005-0092964, filed Oct. 4, 2005, the subject matter of which is hereby incorporated by reference in its entirety.

2. Discussion of Related Art

The recent evolution of semiconductor devices is one characterized by increasing component densities, greater device integration, and higher operating speeds. These trends require the accurate formation of ever smaller structures, components and particular regions (hereafter, collectively and/or separately referred to in generic form as “elements” of a semiconductor device).

Generally, the manufacture of such elements is accomplished through the application of a complex sequence of fabrication processes. One common type of fabrication process involves the selective implantation of ions (e.g., conductive impurities) into defined regions of a semiconductor substrate. Chemical elements selected from group III or group IV are commonly used as implantation ions.

Other fabrication processes include, thin film deposition processes adapted to form a material film on the semiconductor substrate, etching processes adapted to pattern one or more material films, chemical mechanical polishing (CMP) processes adapted to planarize the surface of a semiconductor substrate, wafer cleaning processes adapted to selectively remove material and/or contaminants from a semiconductor substrate, etc. During the fabrication of a semiconductor device, these process types may be repeatedly performed in specially adapted processing equipment.

Many fabrication processes use plasma to good effect. For example, plasma has been used in various dry etch processes (e.g., anisotropic etching processes) adapted to selectively form patterns in a material film, and certain ashing processes adapted to remove a photoresist layer, etc.

Plasma comprises one or more gases placed in a high energy state. This high energy state ionizes the constituent gasses. That is, the addition of sufficient energy to a confined gas causes a great number of high energy collisions between gas atoms. These collisions liberate electrons from the colliding atoms and thereby ionize the gas.

Unlike simple heated gas which consists primarily of electrically neutral atoms, plasma consists of charged particles (e.g., positively charged “ions” and negatively charged “electrons” created by ionization of the gas). By applying an electric field to the plasma a corresponding magnetic field is induced and a directional flow of charged particles may be generated. In effect, the applied electric field forms a local charge separation means capable of directing the flow of ions and electrons. Thus, while the electric and magnetic fields have very complex mechanical (e.g., direction-imparting) properties, they may be precisely controlled in their general effect.

FIGS. 1A and 1B schematically illustrate an exemplary dry etching process using plasma.

Referring first to FIG. 1A, a target layer 12 to be patterned by the dry etch process is formed on an underlayer 10 such as a semiconductor substrate. A photoresist pattern 14 selectively exposes target layer 12. A plasma is formed in a process chamber holding the work piece. An oxygen (O) plasma is assumed in this example comprising positively charged O+ ions, negatively charged electrons, and neutral O* radicals. Argon (Ar) ions may be used within the plasma to break the ionic bonds in native oxygen molecules (O2).

Referring now to FIG. 1B, once the oxygen plasma is formed, a negative voltage is applied to underlayer 10. In response to this applied bias voltage positively charged particles within the plasma are drawn towards target layer 12. The impact on, and resulting absorption of these positively charged particles within the exposed portions of target layer 12 resulting in an etching phenomenon. In effect, the positively charged particles result in ionic collisions and chemical reaction with target layer 12. A material transformation of the exposed portions of target layer 12 create a volatile byproduct that may be readily removed.

This type of plasma etching process has many advantages including the requirement to apply only a relatively low plasma voltage, and very good material selectivity. Also, plasma etching may be conducted at relatively low temperatures which prevents deterioration of the semiconductor substrate.

FIGS. 2 and 3 illustrate profiles of the edge regions of two exemplary gate oxide layers. The gate oxide layer shown in FIG. 2 is formed using thermal energy, while the gate oxide layer shown in FIG. 3 is formed using plasma.

Referring to FIG. 2, a gate oxide layer (Gox) 24 is formed using a thermal oxidation process on the active region of a silicon substrate 20, as defined by an isolation region 22 formed using a shallow trench isolation (STI) technique. Thereafter, a polysilicon layer 26 functioning as a gate electrode is formed on gate oxide layer 24.

In forming an oxide layer on a silicon layer using thermal energy, the growth rate of the oxide layer will vary in relation to its surface orientation. Thus, the resulting oxide layer is thinner in a direction perpendicular to silicon substrate 20, because the growth plane in this direction is limited to the bond between a single silicon atom and two oxygen atoms. As a result, the portion of gate oxide layer 24 formed over an edge of isolation region 22 is quite thin and exhibits poor step coverage. (See, region “A” in FIG. 2). This uneven gate oxide thickness and poor step coverage results in degraded electrical properties for the constituent semiconductor devices and diminished reliability in host devices incorporating the semiconductor device.

Because of these problems, thermal oxidation processes have largely been discarded in favor of plasma oxidation processes in the fabrication of conventional semiconductor devices.

Referring to FIG. 3, a gate oxide layer 34 is formed using an oxygen plasma process on the active region of a silicon substrate 30, as defined by an isolation region 32 formed using a shallow trench isolation (STI) technique. Thereafter, a polysilicon layer 36 functioning as a gate electrode is formed on gate oxide layer 34.

The plasma-formed oxide layer 34 grows on the underlying silicon substrate 30 without regard to surface orientation. Thus, the interface defects noted above with respect to the silicon oxide layer and the silicon layer (e.g., the weak Si-Si bonding, strained Si-O bonding, and Si dangling bonding) are mitigated by the use of highly reactive oxygen radicals to thereby improve the quality of the resulting oxide layer. (See, region “B” of FIG. 3). As a result, gate oxide layer 34 is formed more uniformly and with better step coverage, particularly over the edge portion of the isolation region 32.

Against this background, it should be further noted that semiconductor devices may be fabricated using batch techniques or single wafer techniques. These disparate fabrication techniques implicate different types of processing equipment. Batch type equipment, which processes a plurality of wafers (20 to 25) loaded into a common wafer boat within a process chamber, is clearly advantageous in the mass production of semiconductor devices. However, batch processing is not well aligned to certain processes such as those adapted to remove a photoresist from the wafers during a photolithography process.

In contrast, single wafer type equipment is generally adapted to perform a process on a single wafer loaded onto a heated chuck within a process chamber. Single wafer type equipment is disadvantageous in its throughput, but very aligned with processes requiring uniformity of process application across high integrated wafers.

In performing a plasma oxidation process, such as the one described with reference with FIG. 3, the effective lifetime of the plasma particles (e.g., oxygen radicals) is relatively short (i.e., the time during which the plasma particles may chemically react with a target layer). Thus, when an oxide layer (e.g., a gate oxide layer) is to be deposited on a semiconductor substrate using plasma, single wafer type equipment is necessarily used. In this way, when the oxide layer is formed using the exemplary plasma noted above, the oxygen radicals “recover” (e.g., remedy) crystal defects inherently in the underlayer upon which oxide layer is formed. Thus, plasma-based processes form very high quality gate oxide layers. Unfortunately, these positive results are conventionally limited to only single wafer type equipment because of the short lifetime of the charged particles in the plasma. This restriction to single wafer type equipment adversely effects productivity of the overall fabrication sequence forming the semiconductor devices.

### SUMMARY OF THE INVENTION

Embodiments of the invention provide a method and an apparatus for manufacturing semiconductor devices using a plasma based process capable of providing very high quality material layers and semiconductor devices having improved reliability.

Thus, in one embodiment, the invention provides an apparatus adapted to the manufacture of semiconductor devices, comprising; a plasma generator adapted to convert a plasma source into plasma comprising plasma particles, a plasma capture portion adapted to receive the plasma and capture the plasma particles in plasma capsules formed from a protective layer, and a process chamber adapted to receive the plasma capsules.

In related aspects, the plasma source may comprise at least one of oxygen, argon, and hydrogen; the plasma generator may convert the plasma source into plasma using radio frequency (RF) or microwave energy; and the protective layer may comprise bubbles formed from H2O or N2.

Embodiments of the invention may be readily adapted to batch type processing equipment or single wafer type processing equipment.

In another embodiment, the invention provides an apparatus adapted to the formation of an oxide layer on a semiconductor substrate, comprising; a plasma generator adapted to convert a plasma source into plasma comprising radicals and charged particles, a plasma capture portion adapted to receive the plasma and capture the radicals and plasma particles in plasma capsules formed from a protective layer, and a process chamber adapted to receive the plasma capsules, liberate the radicals, and form the oxide layer on the semiconductor substrate via a radical oxidation process using the liberated radicals.

In yet another embodiment, the invention provides a method for forming a material layer on a semiconductor substrate, the method comprising; converting a plasma source into plasma comprising plasma particles, capturing the plasma particles in plasma capsules formed from a protective layer, injecting the plasma capsules into a process chamber and rupturing the plasma capsules using collision energy between the plasma capsules to reactivate the plasma particles captured in the plasma capsules, and forming the material layer on the semiconductor substrate using the plasma particles.

### BRIEF DESCRIPTION OF THE DRAWINGS

Embodiments of the invention will be described with reference to the attached drawings in which:

FIGS. 1A and 1B are schematic views illustrating a conventional and generic dry etching process using plasma;

FIG. 2 is a sectional view of a conventional semiconductor device showing a gate oxidation layer formed using a thermal oxidation process;

FIG. 3 is a sectional view of a conventional semiconductor device showing a gate oxidation layer formed using a plasma oxidation process;

FIG. 4 is a view of an apparatus for manufacturing semiconductor devices using a plasma based process according to embodiment of the invention;

FIG. 5 is a flow chart illustrating a method for manufacturing semiconductor devices using the manufacturing apparatus of FIG. 4;

FIG. 6 is a schematic view illustrating plasma particles captured by bubbles formed from H2O or N2; and

FIGS. 7A through 7C are schematic views illustrating an exemplary process of forming an oxide layer using oxygen radicals.

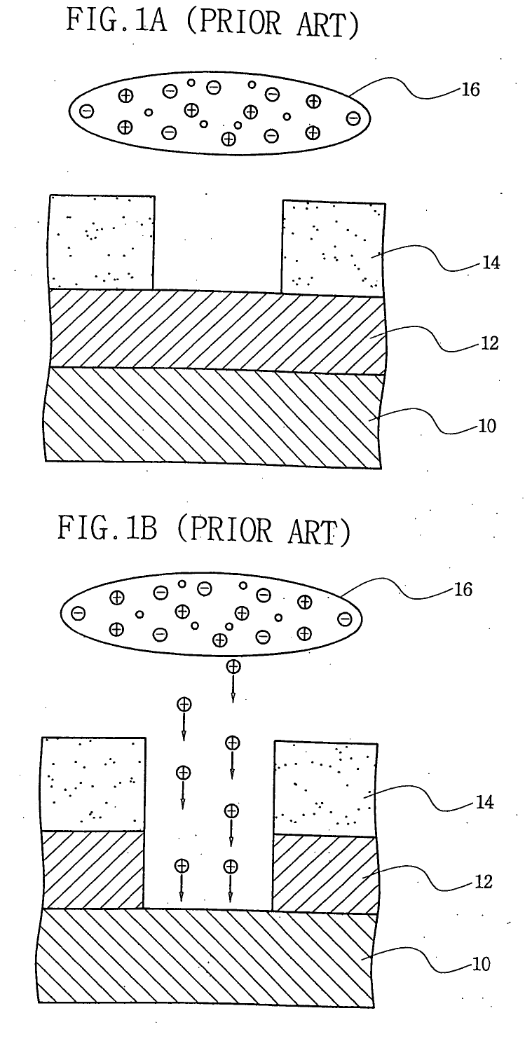

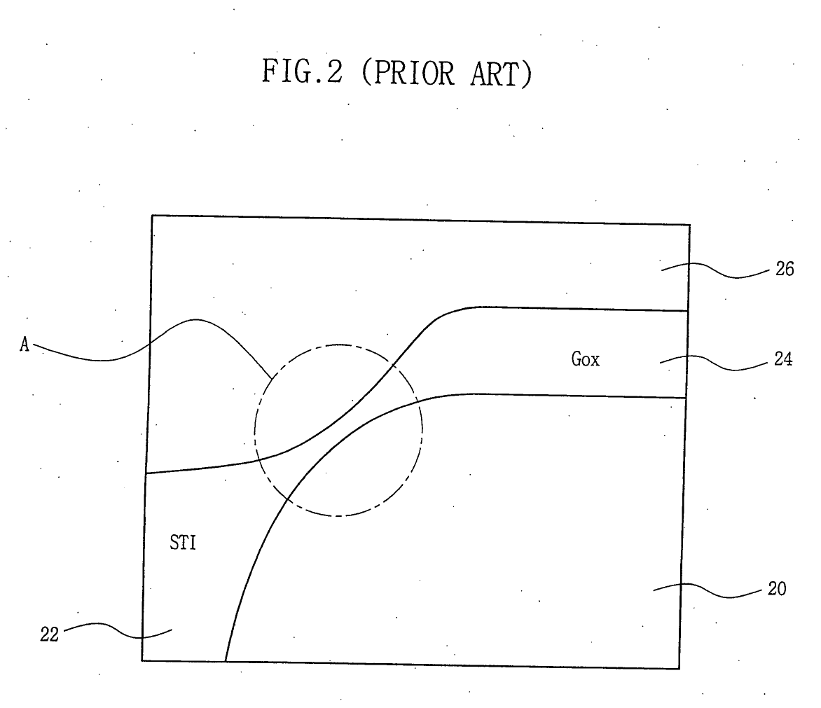

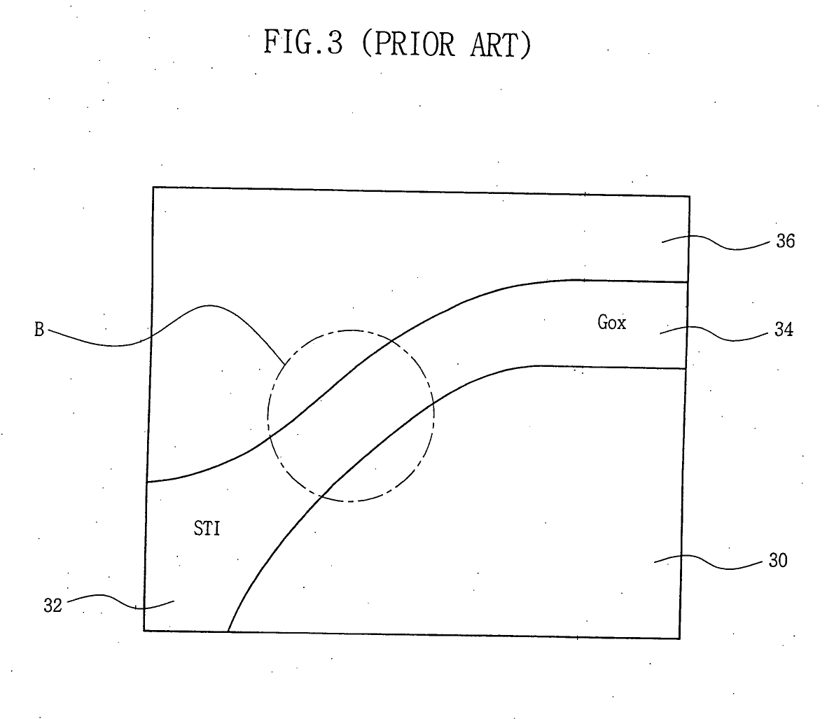

### DESCRIPTION OF EXEMPLARY EMBODIMENTS

Embodiments of the invention will now be described with reference to the accompanying drawings. However, the invention should not be construed as being limited to only the illustrated embodiments. Rather, the embodiments are presented as teaching examples. In the drawings, like numbers refer to like elements.

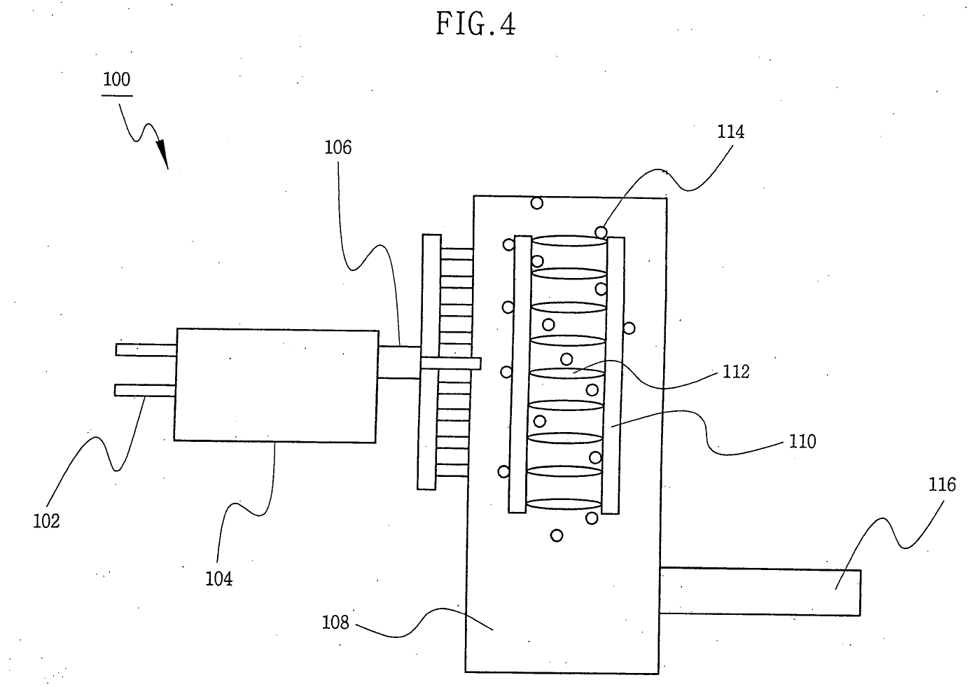

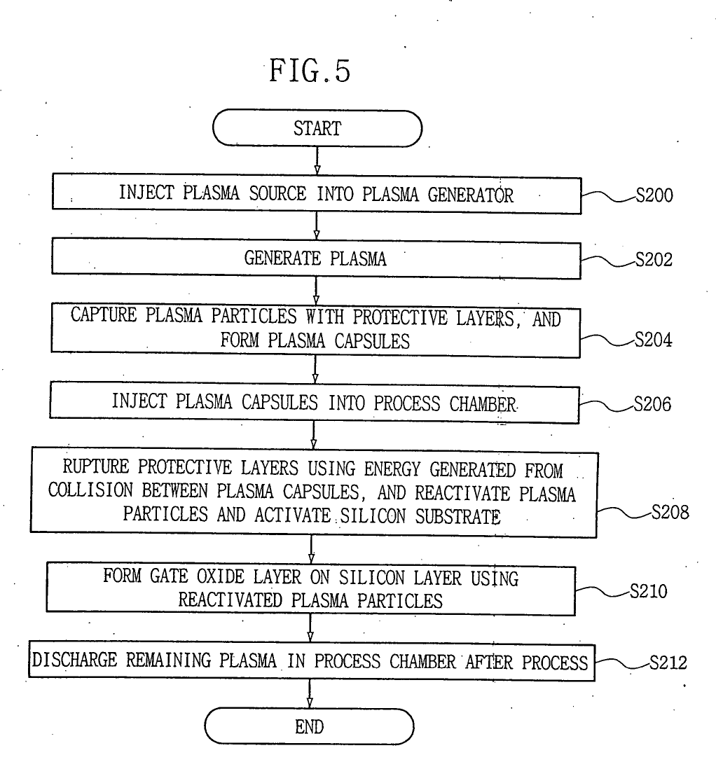

FIG. 4 shows a batch type processing apparatus 100 adapted to the manufacture of semiconductor devices using plasma based processes. FIG. 5 is a related flow chart illustrating an exemplary method of manufacturing semiconductor devices using the apparatus shown in FIG. 4.

Referring first to FIG. 4, apparatus 100 comprises a source injection line 102 through which a plasma source is injected, a plasma generator 104 adapted to generate plasma from the plasma source, a plasma capture portion 106 adapted to capture plasma particles generated from plasma generator 104, a process chamber 108, and an exhaust line 116 adapted to discharge process gas from process chamber 108. A batch cassette 110 adapted to receive a plurality of wafers 112 is provided within process chamber 108.

The related processes of generating plasma and capturing it using plasma capture portion 106 will be now described in some additional detail with reference to FIGS. 4 and 5.

First, a plasma source (e.g., one or more gases) is injected into plasma generator 104 through source injection line 102 (S200). For example, assuming a process adapted to form a gate oxide layer on the active region of a semiconductor substrate, as defined by an isolation layer formed using shallow trench isolation (STI) techniques, the plasma source may comprise, oxygen (O2) and argon (Ar) gas, or oxygen (O2) and hydrogen (H2). Radio frequency (RF) or microwave energy is applied then applied to the plasma source within plasma generator 104 to generate plasma (S202). For example, assuming O2 and Ar have been injected as a plasma source, the resulting plasma will comprise positively charged O+ ions, negatively charged electrons, neutral O* radicals, and Ar ions which serve to break the atomic bonds of the oxygen molecules (O2).

Once generated, the plasma is captured in plasma capture portion 106 disposed between plasma generator 104 and process chamber 108 (S204). In one embodiment, as described in more detail below, the plasma is captured in a protective layer, (e.g., a protective layer comprising bubbles generated from water (H2O) or liquified nitrogen (N2).

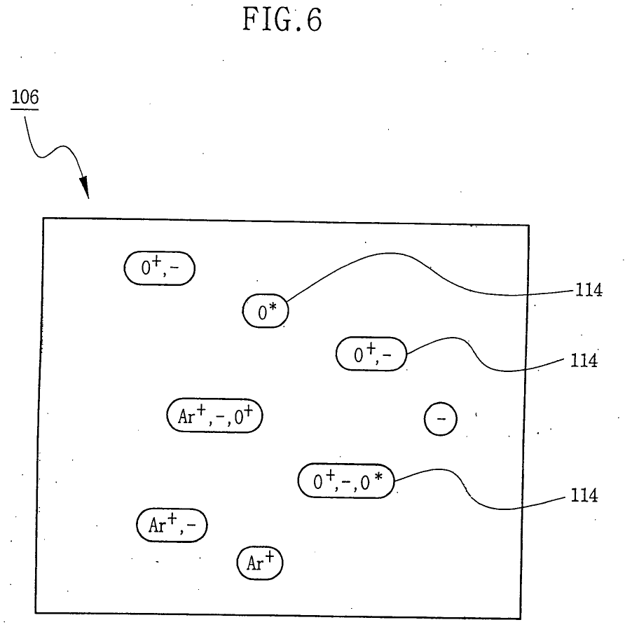

FIG. 6 is a schematic view illustrating an exemplary process whereby plasma particles are captured in a protective layer comprising bubbles formed from H2O or N2.

Referring to FIG. 6, the plasma particles (e.g., O+, O*, electron, and Ar+) generated by plasma generator 104 are randomly captured by the protective layer to variously form plasma capsules 114. Thus, O+, Ar+ and electrons are captured by the protective layer, as well as O* radicals more particularly concerned with formation of an oxide layer within the context of the working example. As variously captured in plasma capsules 114, the charged plasma particles will bond to one another and lose much of their energy.

Then, plasma capsules 114 are injected into process chamber 108 and used to form a gate oxide layer (S206). The illustrated process chamber is batch type, but a single wafer type chamber might just as easily be used.

Since a high percentage of charged plasma particles have been captured in plasma capsules 114, and their high energy state thereby neutralized, such particles do not materially react with the plurality of wafers (e.g., silicon substrates) being processed in process chamber 108. However, plasma capsules 114 injected in process chamber 108 will collide with each other with great kinetic energy, and after a time, will rupture as a result of these collisions. When plasma capsules 114 rupture, the charged plasma particles temporarily bonded to one another with the respective capsules are liberated and return to a high energy state. In addition, the bonding force between the material particles forming the plurality of wafer 112 (e.g., silicon atoms in semiconductor substrates) will be weakened and placed in a state suitable to the formation of an oxide layer (S208). The oxygen radicals in the plasma reactivated by the collision energy of plasma capsules 114 are diffused into and chemically react with the wafer material now having a weakened bonding force in order to form an oxide layer (e.g., a gate oxide layer) on respective active regions of the plurality of wafers 112 (S210). Following formation of the oxide layer, the remaining plasma and any resulting byproducts are discharged from process chamber 108 through exhaust line 116 (S212).

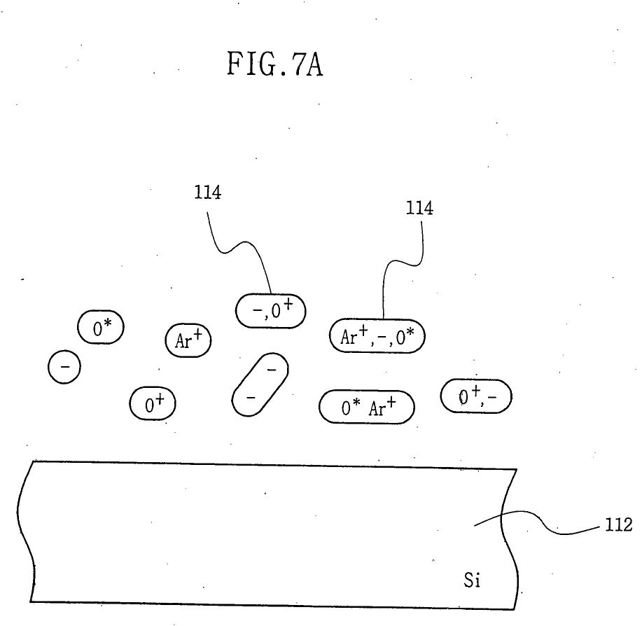

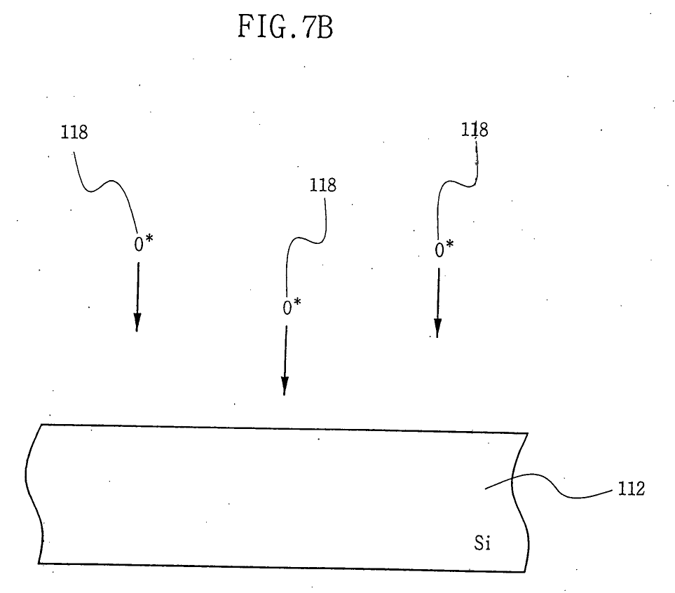

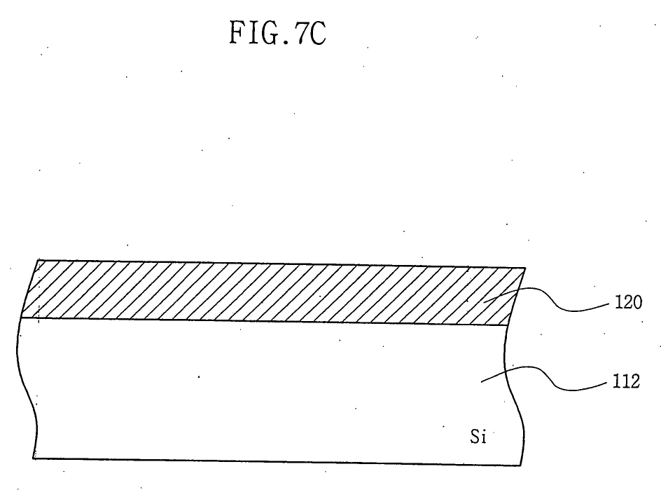

Reference will now be made to FIGS. 7A through 7C, which illustrate an exemplary process adapted to the formation of an oxide layer using oxygen radicals.

Referring first to FIG. 7A, a silicon wafer 112 is exposed to various plasma capsules 114 injected into process chamber 108. These plasma capsules may be formed in one embodiment by bubbles generated from H2O or N2.

Referring to FIG. 7B, plasma capsules 114 injected into process chamber 108 collide with one another and encapsulating bubbles are ruptured by the collision energy. In this manner, charged plasma particles, as well as oxygen radicals 118 in particular, are liberated (or more accurately re-liberated) with great energy. At the same time, the energy resulting from the collision of plasma capsules also weakens the atomic bonds of the silicon atoms forming wafer 112, and silicon particles are energized in a manner that facilitates the formation of the oxide layer.

Finally, referring to FIG. 7C, activated oxygen radicals 118 chemically react with the energized silicon atoms to form a high quality oxide layer 120 characterized by very good step coverage.

Unlike conventional, thermal oxidation processes, the foregoing, exemplary method forms an oxide layer having a highly uniform thickness. In particular, in a case where a gate oxide layer is formed over the edge portion of an isolation region (e.g., an isolation region formed using an STO technique), the gate oxide layer has very good step coverage. In addition, interface defects inherently existing between the silicon oxide layer and the silicon layer (e.g., weak Si-Si bonding, strained Si-O bonding, and Si dangling bonding) are remedied by application of the highly reactive oxygen atoms, so step coverage of the oxide layer as well as the overall quality of the oxide layer are generally improved. Greater reliability in the constituent semiconductor device is thus achieved.

Further, embodiments of the invention may be readily applied to batch type processing equipment in contrast to conventional plasma oxidation processes that are limited to single wafer type processing equipment because of the short lived charged plasma particles. The disadvantages associated with single wafer type processing equipment may thus be avoided.

This significant benefit is imparted by the capturing process provided by the plasma capsules. In effect, the lifetime of charged plasma particles is extended by the capture and re-activation processes described above in the context of a plasma oxidation process. Through this extension of the effective lifetime of plasma particles, a plasma based process may be applied to a plurality of wafers being processed in batch type processing equipment with excellent results and improved productivity.

The invention has been described in the context of exemplary embodiments. However, various modifications and alternative arrangements may be made to the foregoing without departing form the scope of the invention as defined by the following claims.

What is claimed is:

1. An apparatus adapted to the manufacture of semiconductor devices, comprising:
a plasma generator adapted to convert a plasma source into plasma comprising plasma particles;
a plasma capture portion adapted to receive the plasma and capture the plasma particles in plasma capsules formed from a protective layer; and
a process chamber adapted to receive the plasma capsules.

2. The apparatus of claim 1, wherein the plasma source comprises oxygen and argon, or comprises oxygen and hydrogen.

3. The apparatus of claim 1, wherein the plasma generator converts the plasma source into plasma using radio frequency (RF) or microwave energy.

4. The apparatus of claim 1, wherein the protective layer comprises bubbles formed from H₂O or N₂.

5. The apparatus of claim 1, wherein the process chamber is batch type processing equipment or single wafer type processing equipment.

6. An apparatus adapted to the formation of an oxide layer on a semiconductor substrate, comprising:
a plasma generator adapted to convert a plasma source into plasma comprising radicals and charged particles;
a plasma capture portion adapted to receive the plasma and capture the radicals and plasma particles in plasma capsules formed from a protective layer; and
a process chamber adapted to receive the plasma capsules, liberate the radicals, and form the oxide layer on the semiconductor substrate via a radical oxidation process using the liberated radicals.

7. The apparatus of claim 6, wherein the plasma source comprises oxygen and argon, or comprises oxygen and hydrogen.

8. The apparatus of claim 6, wherein the plasma generator converts the plasma source into plasma using radio frequency (RF) or microwave energy.

9. The apparatus of claim 6, wherein the protective layer comprises bubbles formed from H₂O or N₂.

10. The apparatus of claim 6, wherein the process chamber is batch type processing equipment or single wafer type processing equipment.

11. A method for forming a material layer on a semiconductor substrate, the method comprising:
converting a plasma source into plasma comprising plasma particles;
capturing the plasma particles in plasma capsules formed from a protective layer;
injecting the plasma capsules into a process chamber and rupturing the plasma capsules using collision energy between the plasma capsules to reactivate the plasma particles captured in the plasma capsules; and,
forming the material layer on the semiconductor substrate using the plasma particles.

12. The method of claim 11, wherein the plasma source comprises oxygen and argon, or comprises oxygen and hydrogen.

13. The method of claim 12, wherein the plasma source comprises oxygen, the plasma particles comprise oxygen radicals, and the material layer is formed via a radical oxidation process.

14. The method of claim 11, wherein the protective layer comprises bubbles formed from H₂O or N₂.

15. The method of claim 11, wherein the process chamber is batch type or single wafer type processing equipment.

16. The method of claim 11, wherein the material layer comprises a gate oxide layer.

17. The method of claim 13, wherein the material layer comprises a gate oxide layer.
